(19) United States
(12) Patent Application Publication
(10) Pub. No.: US 2016/0294419 A1
(43) Pub. Date: Oct. 6, 2016

(54) CODING AND DECODING METHODS AND APPARATUS

(71) Applicant: KABUSHIKI KAISHA TOSHIBA, Minato-ku, Tokyo (JP)

(72) Inventors: Magnus Stig Torsten SANDELL, Bristol (GB); Filippo TOSATO, Bristol (GB)

(73) Assignee: KABUSHIKI KAISHA TOSHIBA, Minato-ku, Tokyo (JP)

(21) Appl. No.: 15/036,287

(22) PCT Filed: Nov. 15, 2013
(86) PCT No.: PCT/GB13/53016

§ 371 Date: May 12, 2016

(51) Int. Cl. H03M 13/15; H03M 13/35; H03M 13/00; G06F 11/10; G06F 3/06

(52) U.S. Cl. CPC H03M 13/154; G06F 11/1076; G06F 3/0619; G06F 3/064; G06F 3/067; H03M 13/616; H03M 13/353; H04W 4/005

(57) ABSTRACT

In an embodiment a method of generating an erasure code for a network comprising a plurality of nodes, wherein the nodes of the network store data symbols and the number of data symbols stored on a first node of the network is different from the number of data symbols stored on a second node of the network, the erasure code indicating the dependance of parity symbols stored by the nodes of the network on the data symbols such that the data symbols stored on nodes of the network can be determined from parity symbols and data symbols stored on other nodes of the network, comprises determining from the distribution of data symbols among the nodes, an optimal parity symbol distribution;based on the optimal parity symbol distribution and the distribution of data symbols, selecting a code generation method; and generating the erasure code using the selected code generation method.

### FIELD

Embodiments described herein relate generally to methods and apparatus for encoding and decoding using erasure codes and to methods and apparatus for generating erasure codes.

### BACKGROUND

Erasure coding involves the introduction of redundancy in coding schemes which makes it possible to reconstruct data that is lost through erasures.

There are many applications of erasure codes including distributed networks in which erasure codes are used to cope with high packet loss; video streaming over lossy channels; distributed network storage and redundant disk drives.

One application of erasure codes is in distributed sensor networks, for example, the monitoring of energy usage. It is envisaged that the modernisation of the existing energy grid to form the so called ‘Smart Grid’ will allow real-time information exchange between the utility provider and consumers to achieve more efficient energy management. Wireless sensor networks are likely to be employed for monitoring consumers' energy consumption and communicating it to the utility provider.

### BRIEF DESCRIPTION OF THE DRAWINGS

In the following, embodiments are described, by way of example only, with reference to the accompanying drawings in which:

FIG. 1 shows a wireless sensor network according to an embodiment;

FIG. 2 shows a vertical array erasure code used in an embodiment;

FIG. 3 shows a smart meter according to an embodiment;

FIG. 4 shows a concentrator node according to an embodiment;

FIG. 5 shows an initialisation method of a sensor network according to an embodiment;

FIG. 6 shows an initialisation method of a sensor network according to an embodiment;

FIG. 7 shows a method carried out on a node of a sensor network in response to the initialisation process in accordance with an embodiment;

FIG. 8 shows a method carried out on a node of a sensor network in response to the initialisation process in accordance with an embodiment;

FIG. 9 shows a method of monitoring energy usage according to an embodiment;

FIG. 10 shows a method of monitoring energy usage according to an embodiment;

FIG. 11 shows a wireless sensor network according to an embodiment;

FIG. 12 shows a vertical array erasure code used in an embodiment;

FIG. 13 shows a vertical array erasure code used in an embodiment;

FIG. 14 shows a vertical array erasure code used in an embodiment;

FIG. 15 shows a method of generating a vertical erasure code according to an embodiment; and

FIG. 16 shows a method of determining a code type for an erasure code according to an embodiment.

### DETAILED DESCRIPTION

In an embodiment a method of generating an erasure code for a network comprising a plurality of nodes, wherein the nodes of the network store data symbols and the number of data symbols stored on a first node of the network is different from the number of data symbols stored on a second node of the network, the erasure code indicating the dependance of parity symbols stored by the nodes of the network on the data symbols such that the data symbols stored on nodes of the network can be determined from parity symbols and data symbols stored on other nodes of the network comprises determining from the distribution of data symbols among the nodes, an optimal parity symbol distribution; based on the optimal parity symbol distribution and the distribution of data symbols, selecting a code generation method; and generating the erasure code using the selected code generation method.

In an embodiment selecting a code generation method comprises selecting a code generation method from: a first method comprising forming a first array indicating the dependance of the parity symbols on the data symbols, wherein the parity symbols and data symbols form a rectangular array; a second method comprising adding at least one dummy data symbol to the data symbols and forming a second array indicating the dependance of the parity symbols on the data symbols; and a third method comprising adding at least on dummy parity symbol to the data symbols and forming a third array indicating the dependance of the parity symbols on the data symbols.

In an embodiment the first method and/or the second method comprises generating a row wise erasure code from the first or second array.

In an embodiment the first method comprises arranging parity symbols by adding the parity symbols for each node to the column of the first array containing the data symbols corresponding to that node.

In an embodiment the second method comprises deriving a generator matrix from the second array and removing at least one row from the generator matrix, the at least one row corresponding to the at least one dummy data symbol.

In an embodiment the third method further comprises forming a generator matrix from the third array and puncturing a column from the generator matrix.

In an embodiment determining an optimal parity symbol distribution comprises calculating an optimal distribution of parity symbols such that the optimal distribution of parity symbols has the minimum number of parity symbols required to correct a set number of missing nodes.

In an embodiment a data processing system comprises a processor configured to carry out the methods described above.

In an embodiment a concerntrator node of a wireless network comprises the data processing system.

In one embodiment a decoder for decoding a received set of blocks is disclosed. A first block of the received set of blocks comprises a first number of data symbols and a second block of the received set of blocks comprises a second number, different from the first number, of data symbols, and wherein blocks of the received set of blocks comprise parity symbols. The decoder comprises storage for a coding matrix which is derived from the Kronecker product of a totally nonsingular matrix with an antidiagonal matrix; and a processor operable to determine data symbols of at least one erased block from the received set of blocks using the coding matrix.

In an embodiment the coding matrix is the Kronecker product of a totally nonsingular matrix with an antidiagonal matrix.

In an embodiment the coding matrix is a matrix derived by removing at least one row from the Kronecker product of a totally nonsingular matrix with an antidiagonal matrix.

In an embodiment the coding matrix is a matrix derived by removing at least one row and at least one column from the Kronecker product of a totally nonsingular matrix with an antidiagonal matrix.

In one embodiment an encoder for encoding a block of a plurality of blocks of an erasure code is disclosed. A first block of the erasure code comprises a first number of data symbols and a second block of the erasure code comprises a second number, different from the first number, of data symbols. The encoder is configured to set a plurality of parity symbols of the block using combinations of data symbols of other blocks of the plurality of blocks selected according to a column of a coding matrix which is derived from the Kronecker product of a totally non-singular matrix with an antidiagonal matrix.

In an embodiment the coding matrix is the Kronecker product of a totally nonsingular matrix with an antidiagonal matrix.

In an embodiment the coding matrix is a matrix derived by removing at least one row from the Kronecker product of a totally nonsingular matrix with an antidiagonal matrix.

In an embodiment the coding matrix is a matrix derived by removing at least one row and at least one column from the Kronecker product of a totally nonsingular matrix with an antidiagonal matrix.

In an embodiment a method of decoding a received set of blocks is disclosed. Blocks of the received set of blocks comprise a plurality of data symbols and a plurality of parity symbols, and wherein a first block of the received set of blocks comprises a first number of data symbols and a second block of the received set of blocks comprises a second number, different from the first number, of data symbols, the received set of blocks being a subset of a complete set of blocks, the complete set of blocks comprising at least one erased block not included in the received set of blocks. The the method comprises determining the data symbols of the at least one erased block using a coding matrix which is derived from the Kronecker product of a totally nonsingular matrix with an antidiagonal matrix.

In an embodiment a method of encoding a block of a plurality of blocks of an erasure code is disclosed. A first block of the erasure code comprises a first number of data symbols and a second block of the erasure code comprises a second number, different from the first number, of data symbols. The method comprises setting the parity symbols of the block using combinations of data symbols of other blocks of the plurality of blocks selected according to a column of an encoding matrix which is derived from the Kronecker product of a totally nonsingular matrix with an antidiagonal matrix.

Embodiments provide a computer program product comprising computer executable instructions which, when executed by a processor, cause the processor to perform methods as set out above. The computer program product may be embodied in a carrier medium, which may be a storage medium or a signal medium. A storage medium may include optical storage means, or magnetic storage means, or electronic storage means.

The described embodiments can be incorporated into a specific hardware device, a general purpose device configured by suitable software, or a combination of both. Aspects can be embodied in a software product, either as a complete software implementation, or as an add-on component for modification or enhancement of existing software (such as a plug in). Such a software product could be embodied in a carrier medium, such as a storage medium (e.g. an optical disk or a mass storage memory such as a FLASH memory) or a signal medium (such as a download). Specific hardware devices suitable for the embodiment could include an application specific device such as an ASIC, an FPGA or a DSP, or other dedicated functional hardware means. The reader will understand that none of the foregoing discussion of embodiment in software or hardware limits future implementation of the invention on yet to be discovered or defined means of execution.

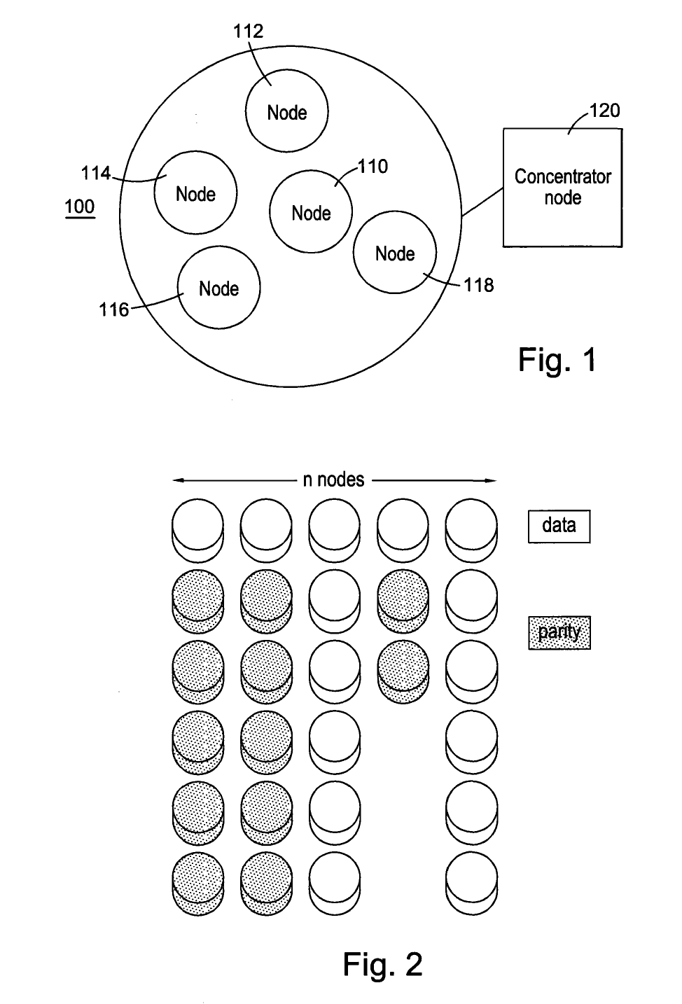

FIG. 1 shows a wireless sensor network according to an embodiment. The wireless sensor network 100 has a plurality of nodes 110, 112, 114, 116 and 118 and a concentrator node 120. Each of the nodes 110, 112, 114, 116 and 118 is a meter in a residential and/or business property. The nodes 110, 112, 114, 116 and 118 monitor consumers' energy consumption and communicate it to the utility provider. The nodes 110, 112, 114, 116 and 118 report their consumption to the concentrator node 120 which is located nearby. Communication between the nodes and/or the concentrator node is wireless, using technology such as IEEE802.11n.

The monitoring of energy usage can be very frequent, for example in the order of seconds, whereas the data gathering by the concentrator node is less frequent, for example in the order of hours or days. This means that data is accumulated and stored at the houses, that is, the nodes in the network and released to the concentrator node upon request. However if all communication is wireless, houses might only be intermittently connected to the concentrator node. At a given time, there is a chance that no reliable communication link is available. In that case, it would be desirable to obtain the data from all nodes by communicating with only a subset of them. This is possible if redundancy is introduced in the network, i.e., the data from one node is stored at one or more other nodes. With an adequate scheme, it could be possible to retrieve the data from all n nodes from only k of them. Another advantage could be that the concentrator node only needs to contact k nodes, even if communication with all nodes is possible.

This can be achieved by employing erasure coding, which makes it possible to reconstruct all the data even if some observations are erased. This is the case if some houses are not able to communicate with the concentrator node. A suitable code is a vertical array code, which is illustrated in FIG. 2.

FIG. 2 shows an irregular array code according to an embodiment. Each column represents a node in the network and consists of its own data and parity symbols for data from other nodes. Note that each node may have different numbers of data and parity symbols. If there are n nodes, the data should be possible to reconstruct from knowing only k of the columns. If the erasure code can correct the maximum number of erased symbols given the redundancy, the code is said to be maximal-distance separable (MDS). It is also important that the parity symbols are a function of as few data symbols as possible, since this minimises the number of data packets needed to be exchanged between the nodes. Erasure codes with this property are called low density.

The way the erasure code works in the context of the sensor network is that each node in the network would generate its own data indicating a reading of, e.g., energy consumption. The node would then share the data with the other nodes in order to have copies of the data in case the node would fail.

Note that all data from one node could simply be copied in full to r other nodes; since the data would then exist in r+1 nodes, the network can cope with r of them failing as at least one copy would survive. However this is an inefficient way of being resilient to node failures; better codes can be designed that can achieve the same level of erasure correction but with much less redundancy and storage. When the concentrator node needs the data from the network, it suffices to connect to k of the n nodes; due to the erasure code the data from the n-k failed nodes can be reconstructed. This is done by using the known dependencies of the data on the parity symbols in the k surviving nodes.

If the array code is applied to, e.g., a sensor network, the data rates might be different since each node in the network act as an independent source. In this case a code must be designed that can cope with multiple irregular sources.

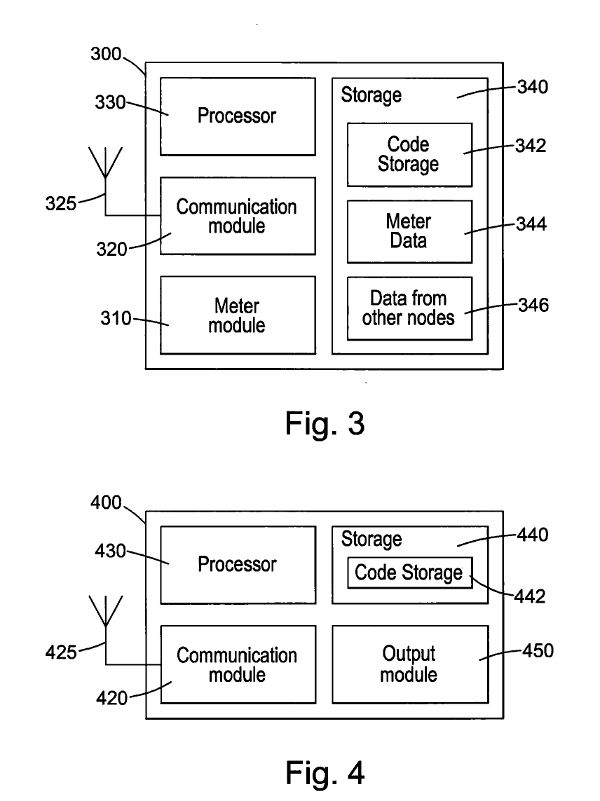

FIG. 3 shows a smart meter according to an embodiment. The smart meter 300 functions as a node in the network 100 shown in FIG. 1. The smart meter 300 has a meter module 310, a communication module 320, a processor 330 and storage 340.

The meter module 310 is configured to monitor energy usage. The communications module is coupled to an antenna 325 and can transmit and receive signals over a wireless network using a wireless protocol such as IEEE802.11n. The storage 340 includes code storage 342, storage for meter data 344 and storage for data received from other nodes 346. The storage may be implemented as volatile memory, non-volatile memory or a combination of both.

In an embodiment, the code storage 342 stores an indexed set of erasure codes and the communications module 320 is operable to receive an indication of an erasure code from the set from the concentrator node.

In an embodiment, the code storage stores an erasure code or a part of a coding matrix which is received over the wireless network from the concentrator node.

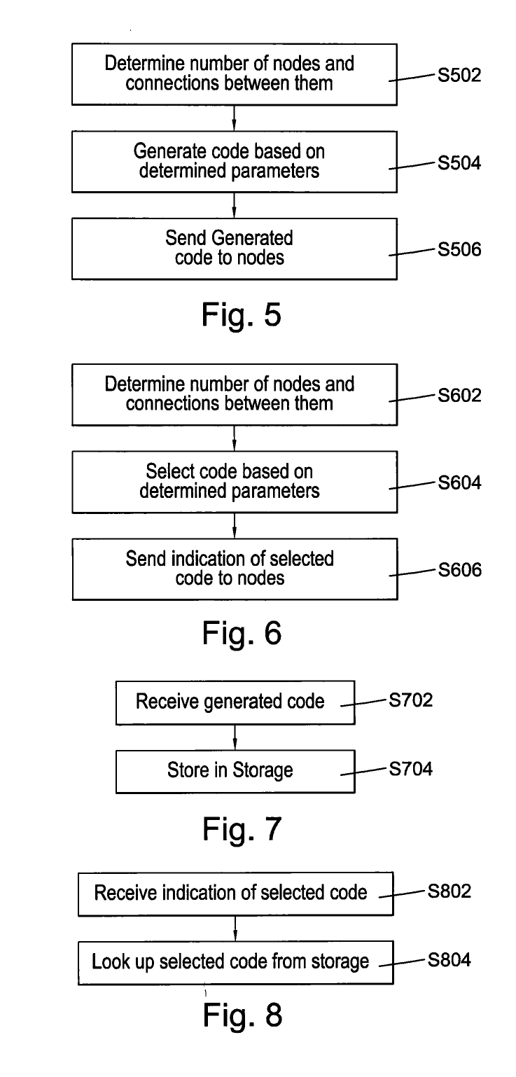

The process by which the indication of the erasure code is selected is described in more detail below with reference to FIGS. 5 and 6.

The processor is operable to generate erasure code blocks encoded using the erasure codes described above which have data symbols indicating the meter data 344 and parity blocks determined from the data from other nodes 346.

FIG. 4 shows a concentrator node 400 according to an embodiment. The concentrator node 400 has a communications module 420, a processor 430, storage 440 and an output module 450. The communication module 420 is coupled to an antenna 425 and can transmit and receive signals over a wireless network using a wireless protocol such as IEEE802.11n. The storage 440 comprises code storage 442.

In an embodiment the code storage 442 of the concentrator node 400 stores an indexed set of erasure codes and the processor is operable to select one of the indexed erasure codes during an initialisation process.

In an embodiment the processor is operable to generate an erasure code during an initialisation process.

The initialisation process is described in more detail below with reference to FIGS. 5 and 6.

FIG. 5 shows an initialisation method according to an embodiment. The steps of the method shown in FIG. 5 are carried out by the concentrator node 400.

In step S502 the concentrator node 400 determines the number of nodes in the network, the data rates and the connections between them.

In step S504 the processor 430 of the concentrator node 400 generates a code based on the determined number of nodes. As discussed above, the methods described herein allow array codes that have the smallest overhead and lowest possible density to be constructed for any number of nodes and that are tolerant of any number of failures. The number of failures may be selectable or may be preset.

In step S506 the generated code is sent to the nodes using the communication module 420 of the concentrator node 400. The code may be sent by sending a coding matrix A to all of the nodes. In an embodiment, the concentrator node sends just the required columns of the coding matrix to each of the nodes.

FIG. 6 shows an initialisation method according to an embodiment. In the method shown in FIG. 6, each of the nodes stores a set of codes that have been pre-calculated using the methods described above. The codes are pre-calculated for different numbers of nodes and may also be pre-calculated for different numbers of failures.

In step S602 the concentrator node 400 determines the number of nodes in the network and the connections between them.

In step S604, the processor selects a stored code based on the number of nodes determined in step S602 and determines an index value indicating the selected code.

In step S606, the concentrator node sends the index value indicating the selected code to the nodes of the network. The nodes of the network also store the indexed set of codes so the selected code can be obtained by the nodes using the index.

FIG. 7 shows a method carried out on a node in response to the initialisation process on the concentrator node according to an embodiment.

In step S702 the node 300 receives a code generated by the concentrator node 400. The code is generated by the concentrator node 400 according to the method described above with reference to FIG. 5.

In step S704 the node 300 stores the received code in the code storage 342 of the node 300. As discussed above, the node may store just the required parts of the coding matrix A.

FIG. 8 shows a method carried out on a node in response to the initialisation process on the concentrator node according to an embodiment.

In step S802 the node 300 receives an indication of a code selected by the concentrator node 400. The indication indicates a code stored in the code storage 342 of the node 400. The indication of the code is generated by the concentrator node 400 according to the method described above with reference to FIG. 6.

In step S804 the node 300 uses the indication to determine which code stored in the code storage 342 to use when encoding.

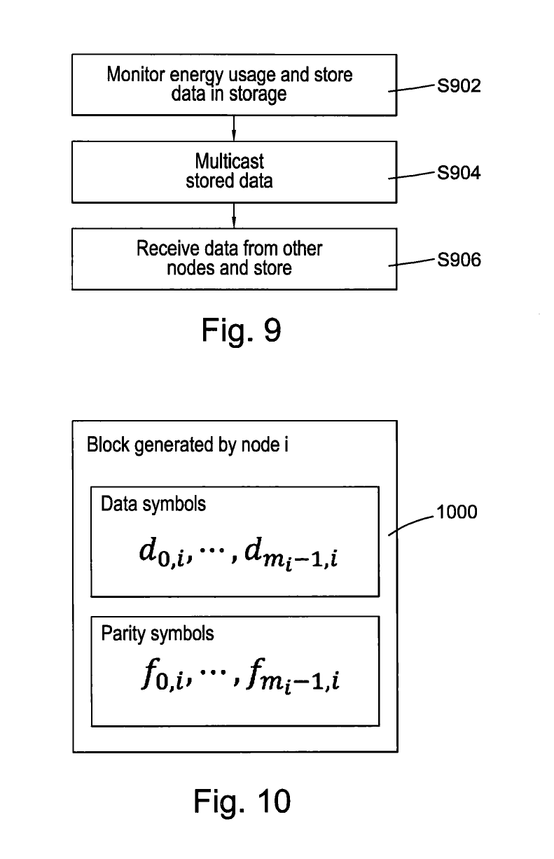

FIG. 9 shows a method of monitoring energy usage carried out by the nodes of a sensor network according to an embodiment.

In step S902 the meter module 310 monitors energy usage and stores data indicating the energy usage in as meter data 344 in the storage 340.

In step S904 the communication module 320 multicasts the meter data 344 stored in the storage 340 to neighbouring nodes.

In step S906 the communication module 320 receives data from other nodes. The received data is stored as data received from other nodes 346 in the storage 340.

Periodically, or in response to a request from the concentrator node, the nodes of the network generate blocks using the stored meter data and the stored data received from other nodes.

FIG. 10 shows a block 1000 generated by a node i of the sensor network. The node has mᵢ data and pᵢ parity symbols (note that these numbers may differ for each node). The block 1000 includes data symbols d_{0,i}, . . . , dₘ_{ᵢ}_{-1,i} and parity symbols f_{0,i}, . . . fₚ_{ᵢ}_{-1,i}. The data symbols are the meter data 344 stored on the node 300. The parity symbols are generated using the erasure code generated or selected by the concentrator node.

In an embodiment the following encoding algorithm is used. The encoding operation consists of generating the parity messages for each of the n nodes. Each parity message is obtained by a linear combination of k data messages provided by other nodes. The multiplications and additions are carried out in GF(q). In particular, the p parity messages for node i are given by

$$( {f}_{1 , i} … {f}_{p , i} ) = d ( \begin{matrix}{A}_{1 , i} \\ ⋮ \\ {A}_{n , i}\end{matrix} ) , i = 1 , … , p \qquad ( 1 )$$

The concentrator node receives blocks generated by the nodes of the network and uses the parity data from the received blocks to recreate the data.

In an embodiment the following decoding algorithm is used. The decoding operation consists in retrieving all the data messages in the event of up to r node failures. Let F={i₁, . . . , iᵣ} be the set of failing nodes and [symbol] ={1, . . . , n}\F={iᵣ₊₁, . . . , iₙ} the set of surviving nodes. The data messages generated by the k surviving nodes can be retrieved directly from these nodes, let these mk messages be grouped as:

dₛ=(d_{1,i}_{ᵣ₊₁} . . . d_{m,i}_{ᵣ₊₁} d_{1,i}_{ᵣ₊₂} . . . d_{m,i}_{ₙ}) (2)

while the remaining mr messages, originated in the failed nodes, form

d_{f}=(d_{1,i}_{₁} . . . d_{m,i}_{₁} d_{1,i}_{₂} . . . d_{m,i}_{ᵣ}) (3)

Accordingly the k block columns of the non-systematic part of the generator matrix corresponding to the surviving nodes can be partitioned as follows

Aₛ= [symbol] (4)

A_{f}= [symbol] (5)

Note that A_{f} is square because mr=pk. The pk parity messages of the surviving nodes can be written as follows

fₛ=(f_{1,i}_{ᵣ₊₁} . . . f_{p,i}_{ᵣ₊₁} f_{1,i}_{ᵣ₊₂} . . . f_{p,i}_{ₙ}) (6)

such that

fₛ=dₛAₛ+d_{f}A_{f} (7)

Therefore, we can solve (7) for the unknowns d_{f}

d_{f}=(fₛ−dₛAₛ)A_{f}⁻¹ (8)

It can be shown that with the construction described above the matrix A_{f} is always non-singular. It is noted that because of the sparse nature of matrix A_{f}, in practice, calculation of (8) can be done in a simplified fashion by solving a number of subsystems that require at most inverting matrices of size min{k,r}.

The decoding algorithm can be formulated in pseudo language as follows

Algorithm 1. Decoding of the MDS code

```
Initialise: i = 1, xⱼ = 0, j = 1, ..., kp
while i ≦ kp do
  if xᵢ = 0 then
    Find all nonzero columns, [symbol]   _{c} = {j|A_{f}(i, j) ≠ 0}, and rows, [symbol]   ᵣ = {l|A_{f}(l, j) ≠ 0, j ε [symbol]
    _{c}}.
    Solve the | [symbol]  ᵣ| × | [symbol]  _{c}| system of equations for the variables d_{t,u}, with m(u − 1) + t =
    l, l ε [symbol]   ᵣ, and u ε [symbol]   , 1 ≦ t ≦ m.
    Mark the variables as solved by setting xₗ = 1, l ε [symbol]   ᵣ.
  end if
                                  i ← i + 1
end while
```

In case less than r nodes fail, hence there are more than k surviving nodes, (8) still applies, where only k of the surviving nodes are used by the concentrator node to retrieve all the information. This reduces the amount of data and parity messages that have to be transferred to the concentrator node. Alternatively, data and parity messages can be collected from all the surviving nodes and (8) still applies with the inverse replaced by the Moore-Penrose pseudo-inverse.

The coding scheme may be adapted to work in an asymmetric network in which the number of data symbols is different for different nodes. The embodiments described in reference to FIGS. 3 to 9 above may be used with the codes described below.

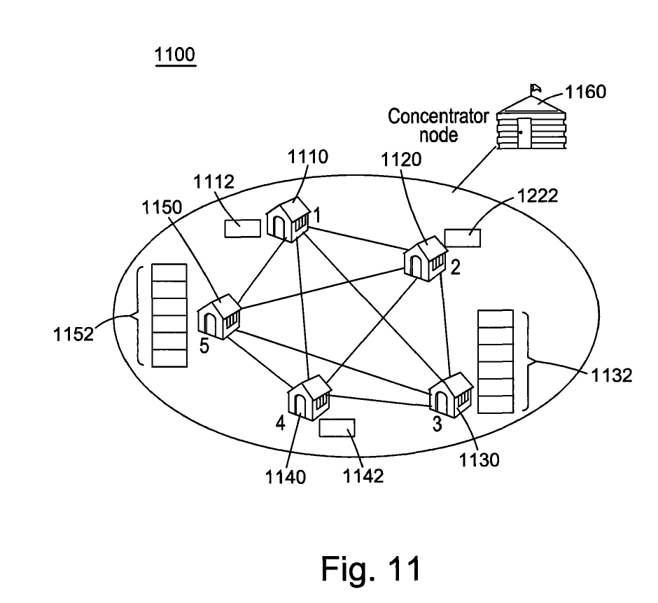

FIG. 11 shows an asymmetric network 1100. The asymmetric network 1100 comprises a first node 1110, a second node 1120, a third node 1130, a fourth node 1140, a fifth node 1150, and a concentrator node 1160. Each of the first to fifth nodes is a meter in a residential or business property. The first to fifth nodes monitor customer's energy usage and communicate this to the concentrator node 1160. Communication between the nodes is wireless using a technology such as IEEE802.11n.

Each of the first to fifth nodes store data symbols indicating the energy usage on that node. As shown in FIG. 11 the number of data symbols stored on each node varies. The first node 1110 stores one data symbol 1112. The second node 1120 stores one data symbol 1122. The third node stores six data symbols 1132. The fourth node 1140 stores one data symbol 1142. The fifth node 1150 stores six data symbols 1152.

The first thing to do when considering an asymmetric network (different amount of data in each node) as depicted in FIG. 11, is to work out how many parity symbols are needed. Assume a network with n nodes that should be able to cope with r=n−k node failures. If the set of failing nodes is denoted by F={i₀, . . . , iᵣ₋₁}, then the surviving nodes are S={iᵣ, . . . , iₙ₋₁}={0, . . . , n−1}\F. In order to recover the erased data symbols, any set of failures must have fewer erased data symbols than surviving parity symbols. To minimise the total overhead, we are then interested in the following integer optimisation problem

$${min}_{{\{ {p}_{i} \}}_{i = 0}^{n - 1}} {\sum }_{i} {p}_{i} \\ s . t . {\sum }_{i ∈ F} {m}_{i} \leq {\sum }_{i ∈ S} {p}_{i} , ∀ F \qquad ( 9 )$$

where mᵢ and pᵢ are the number of data and parity symbols per node, respectively.

For an optimal distribution pᵢ*, there must be at least one set of failures F* (or equivalently survivors S*) that fulfils the constraint in (9) with equality. The solution is a type of water filling

$${p}_{i}^{*} = \{ \begin{matrix}max \{ μ - {m}_{i} , 0 \} , & i ∈ {F}^{*} \\ {p}_{i} , such that {\sum }_{i ∈ {S}^{*}} {p}_{i} = {\sum }_{j ∈ {F}^{*}} {m}_{j} , 0 \leq {p}_{i} \leq μ - {m}_{i} , & i ∈ {S}^{*}\end{matrix} \qquad ( 10 )$$

where the water level is

$$μ = max \{ {min}_{i ∈ {F}^{*}} {m}_{i} , {max}_{i ∈ {S}^{*}} {m}_{i} , ⌈ \frac{{\sum }_{i} {m}_{i}}{k} ⌉ \} . \qquad ( 11 )$$

The total number of parity symbols can be shown to be

$${\sum }_{i} {p}_{i}^{*} = {\sum }_{i ∈ {F}^{*}} ( {m}_{i} + max ( μ - {m}_{i} , 0 ) ) \qquad ( 12 )$$

In practice it is difficult to find the set F*, so it may be necessary to check all (ᵣⁿ) combinations, find the tentative water level μ as described in (11) and then compute the number of parity symbols according to (12). The combination that offers the smallest number of parity symbols is chosen; the distribution of parity symbols pᵢ is then given by (10). An example of adding parity symbols to a network with different number of data symbols is shown in FIG. 2.

Once the minimum number of parity symbols and their distribution have been computed, the erasure code needs to be designed. Note that there might be more than one solution to the parity symbol distribution problem.

Given the number of data and parity symbols per node, the encoded array can be written as

$$( \begin{matrix}{d}_{0 , 0} & {d}_{0 , 1} & … & {d}_{0 , n - 1} \\ ⋮ & ⋮ & ⋱ & ⋮ \\ {d}_{{m}_{0} - 1 , 0} & {d}_{{m}_{1} - 1 , 1} & … & {d}_{{m}_{n - 1} - 1 , n - 1} \\ {f}_{0 , 0} & {f}_{0 , 1} & … & {f}_{0 , n - 1} \\ ⋮ & ⋮ & ⋱ & ⋮ \\ {f}_{{p}_{0} - 1 , 0} & {f}_{{p}_{1} - 1 , 1} & … & {f}_{{p}_{n - 1} - 1 , n - 1}\end{matrix} )$$

where d_{i,j} and f_{i,j} are the ith data and parity symbols for node j, respectively, taken from a finite field F_{q}=GF(q) where q=b^{l} is a power of a prime number b. Note that it is not necessarily a regular array since mᵢ+pᵢ may be different for different nodes i. The encoding operation can be written as a vector-matrix multiplication

c=dG (13)

where c is the codeword

c=(d_{0,0} . . . dₘ_{ₒ}_{-1,0}d_{0,1} . . . dₘ_{_{n−1}}_{-1,n-1}f_{0,0} . . . fₚ_{ₒ}_{-1,0}f_{0,1} . . . fₚ_{_{n−1}}_{-1,n-1})

d is the vector of data symbols

d=(d_{0,0} . . . dₘ_{ₒ}_{-1,0} d_{0,1} . . . dₘ_{_{n−1}}_{-1,n-1}) (14)

and G=(I A) is the (Σᵢ mᵢ)×(Σᵢ(mᵢ+pᵢ)) generator matrix. The systematic part of G, of size (Σᵢ mᵢ)×(Σᵢ mᵢ), is the identity matrix I and the nonsystematic part, of size (Σᵢ mᵢ)×(Σᵢ pᵢ), is denoted by A.

For the actual design of A we can divide all possible data distributions into three cases:

Type 1 Codes: mᵢ+pᵢ is Constant

It can be shown that when k divides Σᵢ mᵢ and

$${max}_{i} {m}_{i} \leq \frac{{\sum }_{i} {m}_{i}}{k} ,$$

the optimal parity distribution is pᵢ=μ−mᵢ and it is unique. Since mᵢ+pᵢ is constant, all nodes have the same total number of symbols and the array is a complete rectangle of size μ×n. In this case, we can arrange the data symbols in the array in the following way: the ith element of d in (14) is placed in row i mod and the next available column without exceeding the limitation on the number of data symbols per column, mᵢ. Each row will now have

$$\frac{{\sum }_{i} {m}_{i}}{μ} = k$$

data symbols and the array can be rowwise encoded with a [n,k] erasure code where the r=n−k parity symbols are put the empty slots in each row. Since this rowwise code can correct r erasures, the array can cope with any r erased columns. The generator matrix for the array can be conveniently be expressed as

$$A = {A}^{′} ⊗ D \\ {A}^{′} ∈ {ℱ}_{q}^{k \times r} totally nonsingular \\ {D}_{i , j} = \{ \begin{matrix}1 , & i + j + 1 mod μ \\ 0 , & otherwise\end{matrix} ∈ {\{ 0 , 1 \}}^{μ \times μ} \qquad ( 15 )$$

where [symbol] denotes the Kronecker product. This code is optimal is the sense of overhead and density. A totally nonsingular matrix (all square submatrices are nonsingular) can be constructed with a Singleton matrix with alphabet size q≧n−1.

Decoding of the array code can be done rowwise since each row is a separate [n, k] code. If the generator matrix A′ corresponds to a Reed-Solomon code, there are several well known decoding algorithms; for a generic totally nonsingular generator matrix A′ we can simply decode by solving the system of equations which includes the r erased symbols and the surviving k symbols.

### EXAMPLE

Consider the case with n=5 nodes with data rates m={3,3,2,2,2} and maximum number of erasures r=2 (and hence k=n−r=3). Then the optimal set is F*={0,1} (and consequently S*={2,3,4}) so the water level is

$${p}_{i}^{*} = \{ \begin{matrix}4 - {m}_{i} , & i ∈ \{ 0 , 1 \} \\ {p}_{i} , such that {\sum }_{i ∈ \{ 2 , 3 , 4 \}} {p}_{i} = {\sum }_{i ∈ \{ 0 , 1 \}} {m}_{i} , 6 , 0 \leq {p}_{i} \leq 4 - {m}_{i} , & i ∈ \{ 2 , 3 , 4 \}\end{matrix} \\ = \{ \begin{matrix}1 , & i ∈ \{ 0 , 1 \} \\ 2 , & i ∈ \{ 2 , 3 , 4 \}\end{matrix} \qquad$$

An optimal parity distribution is then

$$μ = max \{ {min}_{i ∈ {F}^{*}} {m}_{i} , {max}_{i ∈ {S}^{*}} {m}_{i} , ⌈ \frac{12}{3} ⌉ \} = 4.$$

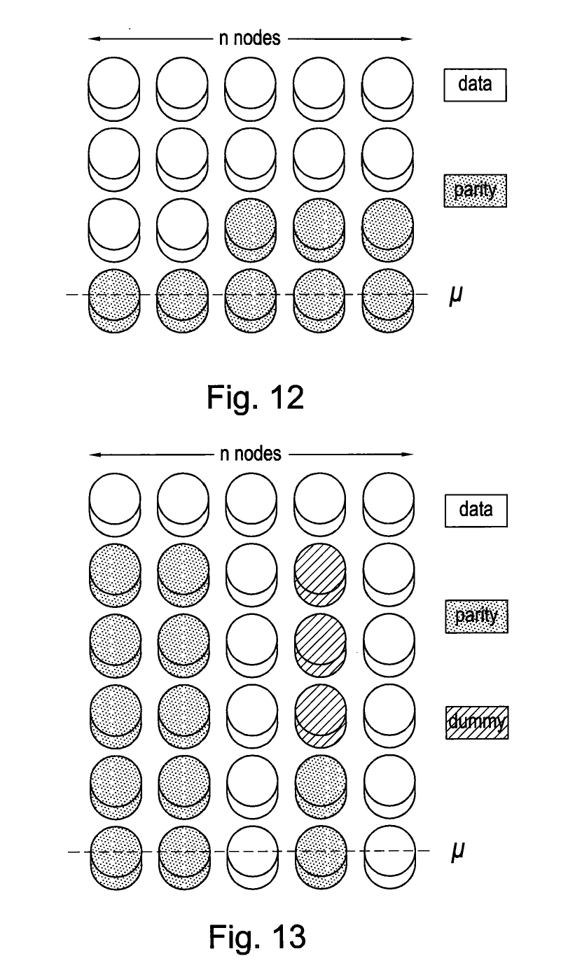

Hence mᵢ+pᵢ=4 is constant for all nodes. This is a unique solution and it is illustrated in FIG. 12. The data vector

d=(d_{0,0} d_{1,0} d_{2,0} d_{0,1} d_{1,1} d_{2,1} d_{0,2} d_{1,2} d_{0,3} d_{1,3} d_{0,4} d_{1,4})

can then be arranged in a 4×5 array as

$$( \begin{matrix}{d}_{0 , 0} & {d}_{1 , 1} & & {d}_{0 , 3} & \\ {d}_{1 , 0} & {d}_{2 , 1} & & {d}_{1 , 3} & \\ {d}_{2 , 0} & & {d}_{0 , 2} & & {d}_{0 , 4} \\ & {d}_{0 , 1} & {d}_{1 , 2} & & {d}_{1 , 4}\end{matrix} )$$

where all rows have k=3 data symbols. Each row can now be encoded with a systematic [5,3] erasure code which is capable of correcting r=2 erasures; hence the whole array can correct any r=2 erased columns. The parity symbols are inserted in the empty slots to complete the array

$$( \begin{matrix}{d}_{0 , 0} & {d}_{1 , 1} & {f}_{1 , 2} & {d}_{0 , 3} & {f}_{1 , 4} \\ {d}_{1 , 0} & {d}_{2 , 1} & {f}_{0 , 2} & {d}_{1 , 3} & {f}_{0 , 4} \\ {d}_{2 , 0} & {f}_{0 , 1} & {d}_{0 , 2} & {f}_{1 , 3} & {d}_{0 , 4} \\ {f}_{0 , 0} & {d}_{0 , 1} & {d}_{1 , 2} & {f}_{0 , 3} & {d}_{1 , 4}\end{matrix} )$$

The rowwise erasure code can be designed with, e.g., a Singleton matrix

$${A}^{′} = ( \begin{matrix}1 & 1 \\ 1 & 4 \\ 1 & 3\end{matrix} )$$

such that the parity symbols are generated as

$$( \begin{matrix}{f}_{1 , 2} & {f}_{1 , 4} \\ {f}_{0 , 2} & {f}_{0 , 4} \\ {f}_{0 , 1} & {f}_{1 , 3} \\ {f}_{0 , 0} & {f}_{0 , 3}\end{matrix} ) = ( \begin{matrix}{d}_{0 , 0} & {d}_{1 , 1} & {d}_{0 , 3} \\ {d}_{1 , 0} & {d}_{2 , 1} & {d}_{1 , 3} \\ {d}_{2 , 0} & {d}_{0 , 2} & {d}_{0 , 4} \\ {d}_{0 , 1} & {d}_{1 , 2} & {d}_{1 , 4}\end{matrix} ) ( \begin{matrix}1 & 1 \\ 1 & 4 \\ 1 & 3\end{matrix} )$$

In equation form the array is encoded as

$$( \begin{matrix}{f}_{0 , 0} & {f}_{0 , 1} & {f}_{0 , 2} & {f}_{1 , 2} & {f}_{0 , 3} & {f}_{1 , 3} & {f}_{0 , 4} & {f}_{1 , 4}\end{matrix} ) = ( \begin{matrix}{d}_{0 , 0} & {d}_{1 , 0} & {d}_{2 , 0} & {d}_{0 , 1} & {d}_{1 , 1} & {d}_{2 , 1} & {d}_{0 , 2} & {d}_{1 , 2} & {d}_{0 , 3} & {d}_{1 , 3} & {d}_{0 , 4} & {d}_{1 , 4}\end{matrix} ) \times ( \begin{matrix}0 & 0 & 0 & 1 & 0 & 0 & 0 & 1 \\ 0 & 0 & 1 & 0 & 0 & 0 & 1 & 0 \\ 0 & 1 & 0 & 0 & 0 & 1 & 0 & 0 \\ 1 & 0 & 0 & 0 & 1 & 0 & 0 & 0 \\ 0 & 0 & 0 & 1 & 0 & 0 & 0 & 4 \\ 0 & 0 & 1 & 0 & 0 & 0 & 4 & 0 \\ 0 & 1 & 0 & 0 & 0 & 4 & 0 & 0 \\ 1 & 0 & 0 & 0 & 4 & 0 & 0 & 0 \\ 0 & 0 & 0 & 1 & 0 & 0 & 0 & 3 \\ 0 & 0 & 1 & 0 & 0 & 0 & 3 & 0 \\ 0 & 1 & 0 & 0 & 0 & 3 & 0 & 0 \\ 1 & 0 & 0 & 0 & 3 & 0 & 0 & 0\end{matrix} ) = dA$$

This generator matrix can be compactly written as

$$A = ( \begin{matrix}1 & 1 \\ 1 & 4 \\ 1 & 3\end{matrix} ) ⊗ ( \begin{matrix}0 & 0 & 0 & 1 \\ 0 & 0 & 1 & 0 \\ 0 & 1 & 0 & 0 \\ 1 & 0 & 0 & 0\end{matrix} ) = {A}^{′} ⊗ D$$

Explicitly, the encoding is then

f=dA

f_{0,0}=d_{0,1}+d_{1,2}+d_{1,4}

f_{0,1}=d_{2,0}+d_{0,2}+d_{0,4}

f_{0,2}=d_{1,0}+d_{2,1}+d_{1,3}

f_{1,2}=d_{0,0}+d_{1,1}+d_{0,3}

f_{0,3}=d_{0,1}+4d_{1,2}+3d_{1,4}

f_{1,3}=d_{2,0}+4d_{0,2}+3d_{0,4}

f_{0,4}=d_{1,0}+4d_{2,1}+3d_{1,3}

f_{1,4}=d_{0,0}+4d_{1,1}+3d_{0,3}

Note that all operations described above are in GF(5).

Type 2 Codes: mᵢ+pᵢ is Not Constant and maxᵢ mᵢ≦μ

If the array is not a complete rectangle, the array code described above can't be used. However if maxᵢ mᵢ≦μ we can add “dummy symbols” to complete the array which is illustrated in FIG. 13. Each node gets \tilde{m}ᵢ=μ−mᵢ−pᵢ extra dummy symbols and it can be shown that the parity symbol distribution pᵢ, which is optimal for the data distribution mᵢ, is also optimal for the data distribution mᵢ+\tilde{m}ᵢ. Hence we can take a code described above for an complete array and use it for the modified system without changing the total number of parity symbols, i.e., the overhead. Since the dummy symbols can be chosen to be any value as they carry no information, we can set them to zero so that they don't contribute to the parity symbols. Thus we can use the erasure code described above for an array of size μ×n (nonsystematic generator matrix A of size (Σᵢ(mᵢ+\tilde{m}ᵢ))×(Σᵢ pᵢ) for the augmented system and then remove the rows of the generator matrix corresponding to the dummy symbols, producing a nonsystematic generator matrix of size (Σᵢ mᵢ)×(Σᵢ pᵢ). This produces an optimal code in terms of overhead and density. Decoding can then be done separately for each row.

### EXAMPLE

Consider the case with n=5 nodes with data rates m={1,1,6,1,6}. We can consider all

$$( \begin{matrix}5 \\ 2\end{matrix} ) = 10$$

possible failure patterns as the optimal failure set F*. One that produces the fewest parity symbols is found to be F*={0,2} and consequently S*={1,3,4}. The water level is

$$μ = max \{ {min}_{i ∈ \{ 0 , 2 \}} {m}_{i} , {max}_{i ∈ \{ 1 , 3 , 4 \}} {m}_{i} , ⌈ \frac{15}{3} ⌉ \} = max \{ 1 , 6 , 5 \} = 6$$

and an optimal distribution is

$${p}_{i}^{*} = \{ \begin{matrix}6 - {m}_{i} , & i ∈ \{ 0 , 2 \} \\ {p}_{i} s . t . {\sum }_{i ∈ \{ 1 , 3 , 4 \}} {p}_{i} = {\sum }_{i ∈ \{ 0 , 2 \}} {m}_{i} = 7 , 0 \leq {p}_{i} \leq 6 - {m}_{i} , & i ∈ \{ 1 , 3 , 4 \}\end{matrix}$$

One such distribution is p={5,5,0,2,0}, although there are three other (equally optimal) distributions since p₁, p₃ and p₄ are not unique. This solution is illustrated in FIG. 12. Since the array is not a complete rectangle, we need to add some dummy symbols. This is shown in FIG. 13 where three dummy symbols are added to node 3. In equation form, the augmented array is

$$( \begin{matrix}{d}_{0 , 0} & & {d}_{4 , 2} & & {d}_{0 , 3} \\ & {d}_{0 , 1} & {d}_{5 , 2} & & {d}_{1 , 3} \\ & & {d}_{0 , 2} & {d}_{0 , 3} & {d}_{2 , 3} \\ & & {d}_{1 , 2} & {d}_{0 , 3}^{′} & {d}_{3 , 3} \\ & & {d}_{2 , 2} & {d}_{1 , 3}^{′} & {d}_{4 , 3} \\ & & {d}_{3 , 2} & {d}_{2 , 3}^{′} & {d}_{5 , 3}\end{matrix} )$$

where d′_{0,3}, d′_{1,3} and d′_{2,3} denote the inserted dummy data symbols. Note that each row has k=3 data symbols each. The array can be completed by adding r=2 parity symbols per row and encoding it rowwise with a [5,3] code

$$( \begin{matrix}{d}_{0 , 0} & {f}_{0 , 1} & {d}_{4 , 2} & {f}_{1 , 3} & {d}_{0 , 4} \\ {f}_{4 , 0} & {d}_{0 , 1} & {d}_{5 , 2} & {f}_{0 , 3} & {d}_{1 , 4} \\ {f}_{3 , 0} & {f}_{4 , 1} & {d}_{0 , 2} & {d}_{0 , 3} & {d}_{2 , 4} \\ {f}_{2 , 0} & {f}_{3 , 1} & {d}_{1 , 2} & {d}_{0 , 3}^{′} & {d}_{3 , 4} \\ {f}_{1 , 0} & {f}_{2 , 1} & {d}_{2 , 2} & {d}_{1 , 3}^{′} & {d}_{4 , 4} \\ {f}_{0 , 0} & {f}_{1 , 1} & {d}_{3 , 2} & {d}_{2 , 3}^{′} & {d}_{5 , 4}\end{matrix} )$$

The rowwise erasure code can be designed with, e.g., a Singleton matrix

$${A}^{′} = ( \begin{matrix}1 & 1 \\ 1 & 4 \\ 1 & 3\end{matrix} )$$

such that the parity symbols are generated as

$$( \begin{matrix}{f}_{0 , 1} & {f}_{1 , 3} \\ {f}_{4 , 0} & {f}_{0 , 3} \\ {f}_{3 , 0} & {f}_{4 , 1} \\ {f}_{2 , 0} & {f}_{3 , 1} \\ {f}_{1 , 0} & {f}_{2 , 1} \\ {f}_{0 , 0} & {f}_{1 , 1}\end{matrix} ) = ( \begin{matrix}{d}_{0 , 0} & {d}_{4 , 2} & {d}_{0 , 4} \\ {d}_{0 , 1} & {d}_{5 , 2} & {d}_{1 , 4} \\ {d}_{0 , 2} & {d}_{0 , 3} & {d}_{2 , 4} \\ {d}_{1 , 2} & {d}_{0 , 3}^{′} & {d}_{3 , 4} \\ {d}_{2 , 2} & {d}_{1 , 3}^{′} & {d}_{4 , 4} \\ {d}_{3 , 2} & {d}_{2 , 3}^{′} & {d}_{5 , 4}\end{matrix} ) ( \begin{matrix}1 & 1 \\ 1 & 4 \\ 1 & 3\end{matrix} )$$

In equation form the array is encoded as

$$( \begin{matrix}{f}_{0 , 0} & {f}_{1 , 0} & {f}_{2 , 0} & {f}_{3 , 0} & {f}_{4 , 0} & {f}_{0 , 1} & {f}_{1 , 1} & {f}_{2 , 1} & {f}_{3 , 1} & {f}_{4 , 1} & {f}_{0 , 3} & {f}_{1 , 3}\end{matrix} ) = ( {d}_{0 , 0} {d}_{0 , 1} {d}_{0 , 2} {d}_{1 , 2} {d}_{2 , 2} {d}_{3 , 2} {d}_{4 , 2} {d}_{5 , 2} {d}_{0 , 3} {d}_{0 , 3}^{′} {d}_{1 , 3}^{′} {d}_{2 , 3}^{′} {d}_{0 , 4} {d}_{1 , 4} {d}_{2 , 4} {d}_{3 , 4} {d}_{4 , 4} {d}_{5 , 4} ) \times ( \begin{matrix}0 & 0 & 0 & 0 & 0 & 1 & 0 & 0 & 0 & 0 & 0 & 1 \\ 0 & 0 & 0 & 0 & 1 & 0 & 0 & 0 & 0 & 0 & 1 & 0 \\ 0 & 0 & 0 & 1 & 0 & 0 & 0 & 0 & 0 & 1 & 0 & 0 \\ 0 & 0 & 1 & 0 & 0 & 0 & 0 & 0 & 1 & 0 & 0 & 0 \\ 0 & 1 & 0 & 0 & 0 & 0 & 0 & 1 & 0 & 0 & 0 & 0 \\ 1 & 0 & 0 & 0 & 0 & 0 & 1 & 0 & 0 & 0 & 0 & 0 \\ 0 & 0 & 0 & 0 & 0 & 1 & 0 & 0 & 0 & 0 & 0 & 4 \\ 0 & 0 & 0 & 0 & 1 & 0 & 0 & 0 & 0 & 0 & 4 & 0 \\ 0 & 0 & 0 & 1 & 0 & 0 & 0 & 0 & 0 & 4 & 0 & 0 \\ 0 & 0 & 1 & 0 & 0 & 0 & 0 & 0 & 4 & 0 & 0 & 0 \\ 0 & 1 & 0 & 0 & 0 & 0 & 0 & 4 & 0 & 0 & 0 & 0 \\ 1 & 0 & 0 & 0 & 0 & 0 & 4 & 0 & 0 & 0 & 0 & 0 \\ 0 & 0 & 0 & 0 & 0 & 1 & 0 & 0 & 0 & 0 & 0 & 3 \\ 0 & 0 & 0 & 0 & 1 & 0 & 0 & 0 & 0 & 0 & 3 & 0 \\ 0 & 0 & 0 & 1 & 0 & 0 & 0 & 0 & 0 & 3 & 0 & 0 \\ 0 & 0 & 1 & 0 & 0 & 0 & 0 & 0 & 3 & 0 & 0 & 0 \\ 0 & 1 & 0 & 0 & 0 & 0 & 0 & 3 & 0 & 0 & 0 & 0 \\ 1 & 0 & 0 & 0 & 0 & 0 & 3 & 0 & 0 & 0 & 0 & 0\end{matrix} ) = \tilde{d} \tilde{A}$$

This generator matrix can be compactly written as

$$\tilde{A} = ( \begin{matrix}1 & 1 \\ 1 & 4 \\ 1 & 3\end{matrix} ) ⊗ ( \begin{matrix}0 & 0 & 0 & 0 & 0 & 1 \\ 0 & 0 & 0 & 0 & 1 & 0 \\ 0 & 0 & 0 & 1 & 0 & 0 \\ 0 & 0 & 1 & 0 & 0 & 0 \\ 0 & 1 & 0 & 0 & 0 & 0 \\ 1 & 0 & 0 & 0 & 0 & 0\end{matrix} ) {A}^{′} ⊗ D$$

The encoding of the parity symbols is now

$$f = \tilde{d} \tilde{A} = ( {d}_{0 , 0} {d}_{0 , 1} {d}_{0 , 2} {d}_{1 , 2} {d}_{2 , 2} {d}_{3 , 2} {d}_{4 , 2} {d}_{5 , 2} {d}_{0 , 3} {d}_{0 , 3}^{′} {d}_{1 , 3}^{′} {d}_{2 , 3}^{′} {d}_{0 , 4} {d}_{1 , 4} {d}_{2 , 4} {d}_{3 , 4} {d}_{4 , 4} {d}_{5 , 4} ) \tilde{A}$$

$${f}_{0 , 0} = {d}_{3 , 2} + {d}_{2 , 3}^{′} + {d}_{5 , 4}$$

$${f}_{1 , 0} = {d}_{2 , 2} + {d}_{1 , 3}^{′} + {d}_{4 , 4}$$

$${f}_{2 , 0} = {d}_{1 , 2} + {d}_{0 , 3}^{′} + {d}_{3 , 4}$$

$${f}_{3 , 0} = {d}_{0 , 2} + {d}_{0 , 3} + {d}_{2 , 4}$$

$${f}_{4 , 0} = {d}_{0 , 1} + {d}_{5 , 2} + {d}_{1 , 4}$$

$${f}_{0 , 1} = {d}_{0 , 0} + {d}_{4 , 2} + {d}_{0 , 4}$$

$${f}_{1 , 1} = {d}_{3 , 2} + 4 {d}_{2 , 3}^{′} + 3 {d}_{5 , 4}$$

$${f}_{2 , 1} = {d}_{2 , 2} + 4 {d}_{1 , 3}^{′} + 3 {d}_{4 , 4}$$

$${f}_{3 , 1} = {d}_{1 , 2} + 4 {d}_{0 , 3}^{′} + 3 {d}_{3 , 4}$$

$${f}_{4 , 1} = {d}_{0 , 2} + 4 {d}_{0 , 3} + 3 {d}_{2 , 4}$$

$${f}_{0 , 3} = {d}_{0 , 1} + 4 {d}_{5 , 2} + 3 {d}_{1 , 4}$$

$${f}_{1 , 3} = {d}_{0 , 0} + 4 {d}_{4 , 2} + 3 {d}_{0 , 4}$$

Since the dummy symbols don't carry any information we set them to a predetermined value, e.g., d′_{0,3}=d′_{1,3}=d′_{2,3}=0. This means that the parity symbols become

f_{0,0}=d_{3,2}+d_{5,4}

f_{1,0}=d_{2,2}+d_{4,4}

f_{2,0}=d_{1,2}+d_{3,4}

f_{3,0}=d_{0,2}+d_{0,3}+d_{2,4}

f_{4,0}=d_{0,1}+d_{5,2}+d_{1,4}

f_{0,1}=d_{0,0}+d_{4,2}+d_{0,4}

f_{1,1}=d_{3,2}+3d_{5,4}

f_{2,1}=d_{2,2}+3d_{4,4}

f_{3,1}=d_{1,2}+3d_{3,4}

f_{4,1}=d_{3,2}+4d_{0,3}+3d_{2,4}

f_{0,3}=d_{3,2}+4d_{5,2}+3d_{1,4}

f_{1,3}=d_{3,2}+4d_{4,2}+3d_{0,4}

which is the same as deleting the corresponding elements (10,11,12) from the augmented data vector \tilde{d} and corresponding rows (10,11,12) from the generator matrix Ã

$$f = d A \\ = ( {d}_{1 , 1} {d}_{1 , 2} {d}_{1 , 3} {d}_{2 , 3} {d}_{3 , 3} {d}_{4 , 3} {d}_{5 , 3} {d}_{6 , 3} {d}_{1 , 4} {d}_{1 , 5} {d}_{2 , 5} {d}_{3 , 5} {d}_{4 , 5} {d}_{5 , 5} {d}_{6 , 5} ) \times \\ ( \begin{matrix}0 & 0 & 0 & 0 & 0 & 1 & 0 & 0 & 0 & 0 & 0 & 1 \\ 0 & 0 & 0 & 0 & 1 & 0 & 0 & 0 & 0 & 0 & 1 & 0 \\ 0 & 0 & 0 & 1 & 0 & 0 & 0 & 0 & 0 & 1 & 0 & 0 \\ 0 & 0 & 1 & 0 & 0 & 0 & 0 & 0 & 1 & 0 & 0 & 0 \\ 0 & 1 & 0 & 0 & 0 & 0 & 0 & 1 & 0 & 0 & 0 & 0 \\ 1 & 0 & 0 & 0 & 0 & 0 & 1 & 0 & 0 & 0 & 0 & 0 \\ 0 & 0 & 0 & 0 & 0 & 1 & 0 & 0 & 0 & 0 & 0 & 4 \\ 0 & 0 & 0 & 0 & 1 & 0 & 0 & 0 & 0 & 0 & 4 & 0 \\ 0 & 0 & 0 & 1 & 0 & 0 & 0 & 0 & 0 & 4 & 0 & 0 \\ 0 & 0 & 0 & 0 & 0 & 1 & 0 & 0 & 0 & 0 & 0 & 3 \\ 0 & 0 & 0 & 0 & 1 & 0 & 0 & 0 & 0 & 0 & 3 & 0 \\ 0 & 0 & 0 & 1 & 0 & 0 & 0 & 0 & 0 & 3 & 0 & 0 \\ 0 & 0 & 1 & 0 & 0 & 0 & 0 & 0 & 3 & 0 & 0 & 0 \\ 0 & 1 & 0 & 0 & 0 & 0 & 0 & 3 & 0 & 0 & 0 & 0 \\ 1 & 0 & 0 & 0 & 0 & 0 & 3 & 0 & 0 & 0 & 0 & 0\end{matrix} )$$

Decoding is then done for each row separately.

Type 3 Codes: mᵢ+pᵢ is Not Constant and maxᵢ mᵢ>μ

Using the same approach in this case, we would need to add dummy symbols to a level of maxᵢ mᵢ to make the array a complete rectangle. However then there will be too many data+dummy symbols for the code to correct r erasures. What we can do instead is to add a few extra parity symbols (and thereby increasing the overhead) and then add dummy symbols to complete the array; these dummy symbols can be removed afterwards as described above. It can be shown that the minimum number of extra parity symbols that needs to be added is r maxᵢ mᵢ−Σᵢ pᵢ; this is in fact the same number of “empty” symbols in F*. Hence these extra parity symbols can be added to the nodes in F*, dummy symbols are then added to complete the array, a rowwise code is designed for the (maxᵢ mᵢ)×n complete array (as in the (mᵢ+pᵢ)=constant case above) and then the rows corresponding to the dummy symbols are deleted from the generator matrix. Puncturing the extra data symbols, i.e. rows from the generator matrix is not enough in this case to produce an optimal code because of the extra parity symbols.

However, once the candidate parity symbols, i.e. columns of the generator matrix, have been chosen, it can be shown that it is always possible to shift the nonzero elements in these columns along their respective rows into positions made available by puncturing the extra rows. These shifted elements are then replaced by the nonzero elements from the same positions in the deleted rows. This procedure generates a number of all-zero columns equal to the number of extra parity symbols, which can then be removed. The resulting reduced generator matrix must be tested to guarantee that all the relevant submatrices have full row rank.

Therefore, puncturing the extra columns requires a search over the possible combinations of horizontal shifts of the nonzero elements in the columns to be deleted. The search can be made more efficient by identifying the combination of extra columns and rows to remove such that the number of elements to shift is minimised. Moreover, we can introduce an order between these candidate sets of columns to be removed such that the first combinations to be tested are those with the fewest nonzero elements.

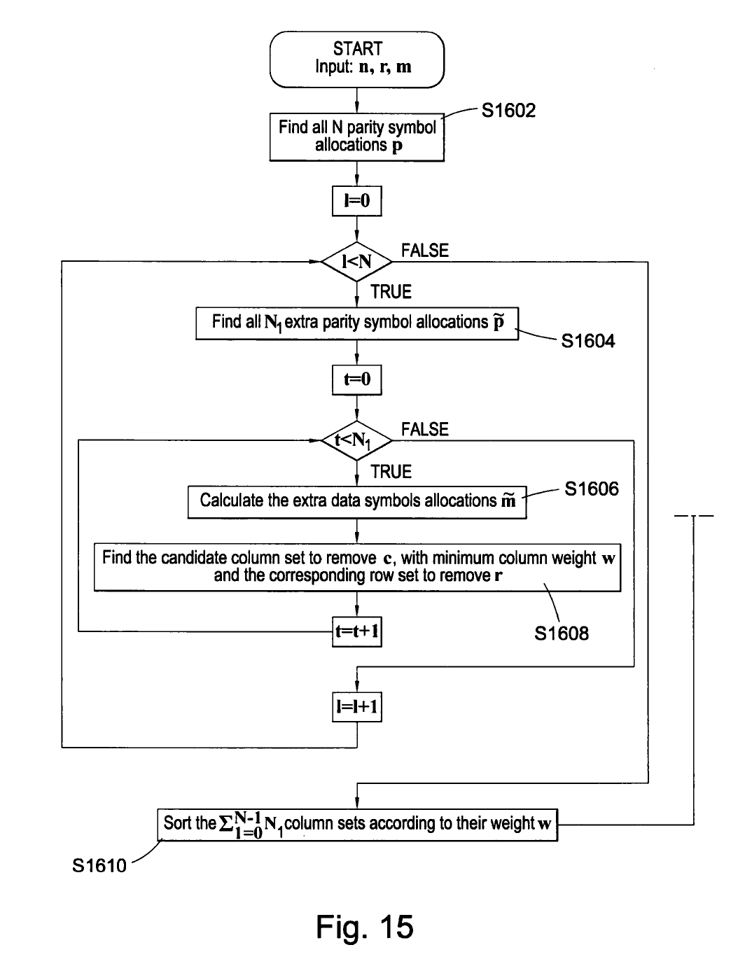

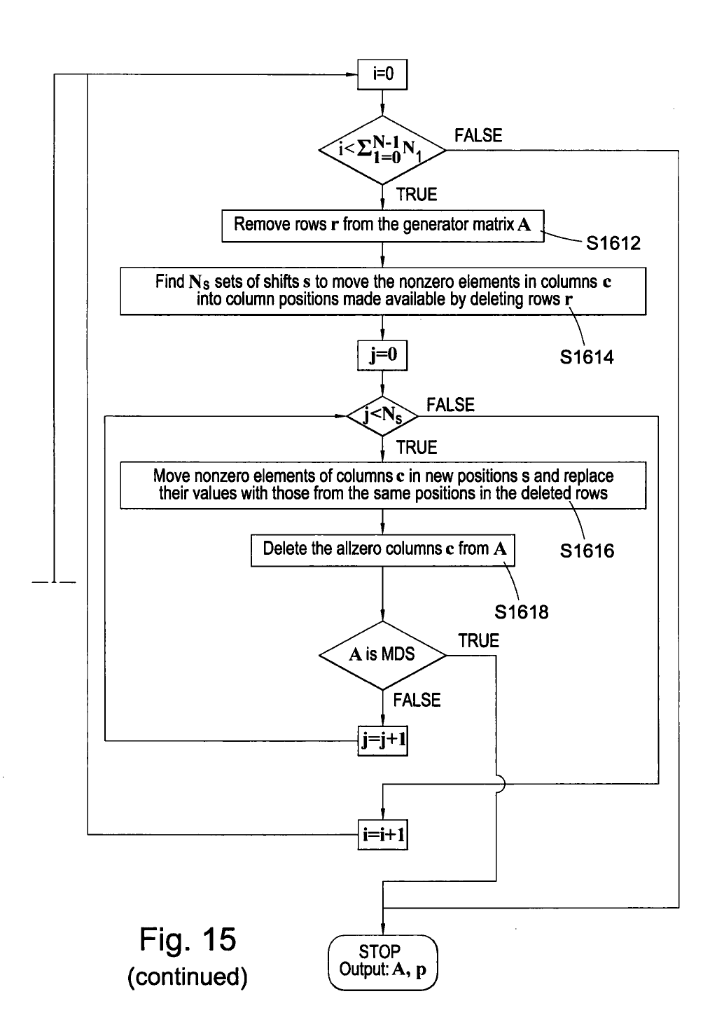

A flow chart of the procedure outlined above is illustrated in FIG. 15, where, for the input parameters given by n, r, and the data distribution m=[m₀, . . . , mₙ₋₁], the algorithm yields an MDS irregular array code with generator matrix A and parity allocation p.

In step S1602 the parity allocations are found. Then in step S1604, the additional dummy parity symbol allocations \tilde{p} are found. In step S1608, the candidate column set c and corresponding row set r to remove with minimum weight w (number of nonzero values) are found.

In step S1610 the columns are sorted according to their weight. In step S1612 the rows r identified in step S1608 are removed from the generator matrix A.

In step S1614 possible sets of shifts to move the nonzero elements in the columns c into column positions made available by the deleting of rows in step S1612.

After the extra rows are removed, the generator matrix is manipulated in such a way that the columns we want to remove are all zeros. To do so, the nonzero elements in these columns are shifted horizontally to other column positions in step S1616. Now, the only candidate shifts are those provided by the locations of the nonzero elements in the removed rows. This is because of the symmetries in the construction of the generator matrix, which make it impossible to shift a nonzero elements to a column already containing k=n−r nonzero elements.

In step S1618, the nonzero columns c are removed from the generator matrix A.

The generator matrix A does not correspond to a rowwise encoding in this case and hence can't be decoded rowwise. However since this is a punctured generator matrix (rows and columns have been removed) of the form A=A′ [symbol] D, we can use the decoding algorithm described above.

### EXAMPLE

Consider the case with n=5 nodes with data rates m={7,6,1,14}. After checking all

$$( \begin{matrix}5 \\ 2\end{matrix} ) = 10$$

possible failure patterns, the one that produces the fewest parity symbols is found to be F*={0,1} and consequently S*={2,3,4}. The water level is

$$μ = max \{ {min}_{i ∈ \{ 0 , 1 \}} {m}_{i} , {max}_{i ∈ \{ 2 , 3 , 4 \}} {m}_{i} , ⌈ \frac{16}{3} ⌉ \} = max \{ 6 , 1 , 6 \} = 6$$

and an optimal distribution is

$${p}_{i}^{*} = \{ \begin{matrix}max \{ 6 - {m}_{i} , 0 \} , & i ∈ \{ 0 , 1 \} \\ {p}_{i} s . t . {\sum }_{i ∈ \{ 2 , 3 , 4 \}} {p}_{i} = {\sum }_{i ∈ \{ 0 , 1 \}} {m}_{i} = 13 , 0 \leq {p}_{i} \leq 6 - {m}_{i} , & i ∈ \{ 2 , 3 , 4 \}\end{matrix}$$

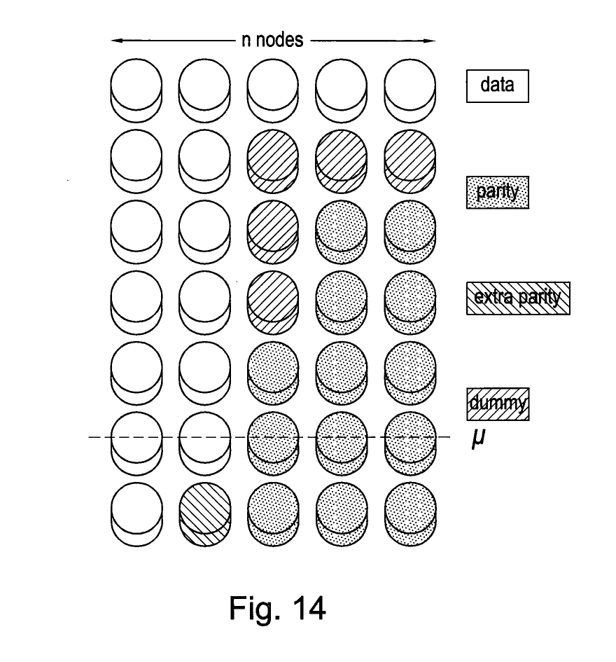

One such distribution is p={0,0,3,5,5}, although there are five other (equally optimal) distributions since p₂, p₃ and p₄ are not unique. However since m₀>μ we would need to fill up the array to the level m₀=7 instead of μ=6 to make it complete; in that case there would not be enough parity symbols to correct r=2 erasures. Instead we can add r maxᵢ mᵢ−Σᵢ pᵢ=2·7−13=1 extra parity symbol to complete the (maxᵢ mᵢ)×r subarray. Then we can add the dummy symbols to complete the array; this procedure is illustrated in FIG. 14. In equation form, the array augmented with the dummy data symbols is

$$( \begin{matrix}{d}_{0 , 0} & {d}_{0 , 1} & {d}_{0 , 2}^{′} & & \\ {d}_{1 , 0} & {d}_{1 , 1} & {d}_{1 , 2}^{′} & & \\ {d}_{2 , 0} & {d}_{2 , 1} & {d}_{2 , 2}^{′} & & \\ {d}_{3 , 0} & {d}_{3 , 1} & & {d}_{0 , 3} & \\ {d}_{4 , 0} & {d}_{4 , 1} & & {d}_{0 , 3}^{′} & \\ {d}_{5 , 0} & {d}_{5 , 1} & & & {d}_{0 , 4} \\ {d}_{6 , 0} & & {d}_{0 , 2} & & {d}_{0 , 4}^{′}\end{matrix} )$$

Note that all rows have k=3 data symbols. We can now encode each row separately and add r=2 parity symbols

$$( \begin{matrix}{d}_{0 , 0} & {d}_{0 , 1} & {d}_{0 , 2}^{′} & {f}_{2 , 3} & {f}_{4 , 4} \\ {d}_{1 , 0} & {d}_{1 , 1} & {d}_{1 , 2}^{′} & {f}_{1 , 3} & {f}_{3 , 4} \\ {d}_{2 , 0} & {d}_{2 , 1} & {d}_{2 , 2}^{′} & {f}_{0 , 3} & {f}_{2 , 4} \\ {d}_{3 , 0} & {d}_{3 , 1} & {f}_{2 , 2} & {d}_{0 , 3} & {f}_{1 , 4} \\ {d}_{4 , 0} & {d}_{4 , 1} & {f}_{1 , 2} & {d}_{0 , 3}^{′} & {f}_{0 , 4} \\ {d}_{5 , 0} & {d}_{5 , 1} & {f}_{0 , 2} & {f}_{4 , 3} & {d}_{0 , 4} \\ {d}_{6 , 0} & {f}_{0 , 1}^{′} & {d}_{0 , 2} & {f}_{3 , 3} & {d}_{0 , 4}^{′}\end{matrix} )$$

Note that f′_{0,1} is the extra parity symbol that was added.

The rowwise erasure code can be designed with, e.g., a Singleton matrix

$${A}^{′} = ( \begin{matrix}1 & 1 \\ 1 & 4 \\ 1 & 3\end{matrix} )$$

such that the parity symbols are generated as

$$( \begin{matrix}{f}_{2 , 3} & {f}_{4 , 4} \\ {f}_{1 , 3} & {f}_{3 , 4} \\ {f}_{0 , 3} & {f}_{2 , 4} \\ {f}_{2 , 2} & {f}_{1 , 4} \\ {f}_{1 , 2} & {f}_{0 , 4} \\ {f}_{0 , 2} & {f}_{4 , 3} \\ {f}_{0 , 1} & {f}_{3 , 3}\end{matrix} ) = ( \begin{matrix}{d}_{0 , 0} & {d}_{0 , 1} & {d}_{0 , 2}^{′} \\ {d}_{1 , 0} & {d}_{1 , 1} & {d}_{1 , 2}^{′} \\ {d}_{2 , 0} & {d}_{2 , 1} & {d}_{2 , 2}^{′} \\ {d}_{3 , 0} & {d}_{3 , 1} & {d}_{0 , 3} \\ {d}_{4 , 0} & {d}_{4 , 1} & {d}_{0 , 3}^{′} \\ {d}_{5 , 0} & {d}_{5 , 1} & {d}_{0 , 4} \\ {d}_{6 , 0} & {d}_{0 , 2} & {d}_{0 , 4}^{′}\end{matrix} ) ( \begin{matrix}1 & 1 \\ 1 & 4 \\ 1 & 3\end{matrix} )$$

In equation form the array is encoded as

$$( \begin{matrix}\begin{matrix}{f}_{0 , 1}^{′} & {f}_{0 , 2} & {f}_{1 , 2} & {f}_{2 , 2} & {f}_{0 , 3} & {f}_{1 , 3} & {f}_{2 , 3}\end{matrix} \\ \begin{matrix}{f}_{3 , 3} & {f}_{4 , 3} & {f}_{0 , 4} & {f}_{1 , 4} & {f}_{2 , 4} & {f}_{3 , 4} & {f}_{4 , 4}\end{matrix}\end{matrix} ) = \\ ( \begin{matrix}{d}_{0 , 0} {d}_{1 , 0} {d}_{2 , 0} {d}_{3 , 0} {d}_{4 , 0} {d}_{5 , 0} {d}_{6 , 0} {d}_{0 , 1} {d}_{1 , 1} {d}_{2 , 1} {d}_{3 , 1} \\ {d}_{4 , 1} {d}_{5 , 1} {d}_{0 , 2} {d}_{0 , 2}^{′} {d}_{1 , 2}^{′} {d}_{2 , 2}^{′} {d}_{0 , 3} {d}_{0 , 3}^{′} {d}_{0 , 4} {d}_{0 , 4}^{′}\end{matrix} ) \times \\ ( \begin{matrix}0 & 0 & 0 & 0 & 0 & 0 & 1 & 0 & 0 & 0 & 0 & 0 & 0 & 1 \\ 0 & 0 & 0 & 0 & 0 & 1 & 0 & 0 & 0 & 0 & 0 & 0 & 1 & 0 \\ 0 & 0 & 0 & 0 & 1 & 0 & 0 & 0 & 0 & 0 & 0 & 1 & 0 & 0 \\ 0 & 0 & 0 & 1 & 0 & 0 & 0 & 0 & 0 & 0 & 1 & 0 & 0 & 0 \\ 0 & 0 & 1 & 0 & 0 & 0 & 0 & 0 & 0 & 1 & 0 & 0 & 0 & 0 \\ 0 & 1 & 0 & 0 & 0 & 0 & 0 & 0 & 1 & 0 & 0 & 0 & 0 & 0 \\ 1 & 0 & 0 & 0 & 0 & 0 & 0 & 1 & 0 & 0 & 0 & 0 & 0 & 0 \\ 0 & 0 & 0 & 0 & 0 & 0 & 1 & 0 & 0 & 0 & 0 & 0 & 0 & 4 \\ 0 & 0 & 0 & 0 & 0 & 1 & 0 & 0 & 0 & 0 & 0 & 0 & 4 & 0 \\ 0 & 0 & 0 & 0 & 1 & 0 & 0 & 0 & 0 & 0 & 0 & 4 & 0 & 0 \\ 0 & 0 & 0 & 1 & 0 & 0 & 0 & 0 & 0 & 0 & 4 & 0 & 0 & 0 \\ 0 & 0 & 1 & 0 & 0 & 0 & 0 & 0 & 0 & 4 & 0 & 0 & 0 & 0 \\ 0 & 1 & 0 & 0 & 0 & 0 & 0 & 0 & 4 & 0 & 0 & 0 & 0 & 0 \\ 1 & 0 & 0 & 0 & 0 & 0 & 0 & 4 & 0 & 0 & 0 & 0 & 0 & 0 \\ 0 & 0 & 0 & 0 & 0 & 0 & 1 & 0 & 0 & 0 & 0 & 0 & 0 & 3 \\ 0 & 0 & 0 & 0 & 0 & 1 & 0 & 0 & 0 & 0 & 0 & 0 & 3 & 0 \\ 0 & 0 & 0 & 0 & 1 & 0 & 0 & 0 & 0 & 0 & 0 & 3 & 0 & 0 \\ 0 & 0 & 0 & 1 & 0 & 0 & 0 & 0 & 0 & 0 & 3 & 0 & 0 & 0 \\ 0 & 0 & 1 & 0 & 0 & 0 & 0 & 0 & 0 & 3 & 0 & 0 & 0 & 0 \\ 0 & 1 & 0 & 0 & 0 & 0 & 0 & 0 & 3 & 0 & 0 & 0 & 0 & 0 \\ 1 & 0 & 0 & 0 & 0 & 0 & 0 & 3 & 0 & 0 & 0 & 0 & 0 & 0\end{matrix} ) = \tilde{d} \tilde{A}$$

This generator matrix can be compactly written as

$$\tilde{A} = ( \begin{matrix}1 & 1 \\ 1 & 4 \\ 1 & 3\end{matrix} ) ⊗ ( \begin{matrix}0 & 0 & 0 & 0 & 0 & 0 & 1 \\ 0 & 0 & 0 & 0 & 0 & 1 & 0 \\ 0 & 0 & 0 & 0 & 1 & 0 & 0 \\ 0 & 0 & 0 & 1 & 0 & 0 & 0 \\ 0 & 0 & 1 & 0 & 0 & 0 & 0 \\ 0 & 1 & 0 & 0 & 0 & 0 & 0 \\ 1 & 0 & 0 & 0 & 0 & 0 & 0\end{matrix} )$$

The encoding of the parity symbols is now

$$\tilde{f} = \tilde{d} \tilde{A} \\ = ( \begin{matrix}{d}_{0 , 0} {d}_{1 , 0} {d}_{2 , 0} {d}_{3 , 0} {d}_{4 , 0} {d}_{5 , 0} {d}_{6 , 0} {d}_{0 , 1} {d}_{1 , 1} {d}_{2 , 1} {d}_{3 , 1} \\ {d}_{4 , 1} {d}_{5 , 1} {d}_{0 , 2} {d}_{0 , 2}^{′} {d}_{1 , 2}^{′} {d}_{2 , 2}^{′} {d}_{0 , 3} {d}_{0 , 3}^{′} {d}_{0 , 4} {d}_{0 , 4}^{′}\end{matrix} ) \tilde{A}$$

$${f}_{0 , 1}^{′} = {d}_{6 , 0} + {d}_{0 , 2}^{′} + {d}_{0 , 4}^{′}$$

$${f}_{0 , 2} = {d}_{5 , 0} + {d}_{5 , 1} + {d}_{0 , 4}$$

$${f}_{1 , 2} = {d}_{4 , 0} + {d}_{4 , 1} + {d}_{0 , 3}$$

$${f}_{2 , 2} = {d}_{3 , 0} + {d}_{3 , 1} + {d}_{0 , 3}^{′}$$

$${f}_{0 , 3} = {d}_{2 , 0} + {d}_{2 , 1} + {d}_{0 , 2}$$

$${f}_{1 , 3} = {d}_{1 , 0} + {d}_{1 , 1} + {d}_{2 , 2}^{′}$$

$${f}_{2 , 3} = {d}_{0 , 0} + {d}_{0 , 1} + {d}_{1 , 2}^{′}$$

$${f}_{3 , 3} = {d}_{6 , 0} + 4 {d}_{0 , 2}^{′} + 3 {d}_{0 , 4}^{′}$$

$${f}_{4 , 3} = {d}_{5 , 0} + 4 {d}_{5 , 1} + 3 {d}_{0 , 4}$$

$${f}_{0 , 4} = {d}_{4 , 0} + 4 {d}_{4 , 1} + 3 {d}_{0 , 3}$$

$${f}_{1 , 4} = {d}_{3 , 0} + 4 {d}_{3 , 1} + 3 {d}_{0 , 3}^{′}$$

$${f}_{2 , 4} = {d}_{2 , 0} + 4 {d}_{2 , 1} + 3 {d}_{0 , 2}$$

$${f}_{3 , 4} = {d}_{1 , 0} + 4 {d}_{1 , 1} + 3 {d}_{2 , 2}^{′}$$

$${f}_{4 , 4} = {d}_{0 , 0} + 4 {d}_{0 , 1} + 3 {d}_{0 , 2}^{′}$$

Since the dummy data symbols don't carry any information we set them to a predetermined value, e.g., d′_{0,2}=d′_{1,2}=d′_{2,2}=d′_{0,3}=d′_{0,4}=0, which is the same as deleting the corresponding elements (14,15,16,18,21) from the augmented data vector \tilde{d} and corresponding rows (14,15,16,18,21) from the generator matrix Ã. This means that the parity symbols become

$${f}_{0 , 1}^{′} = {d}_{6 , 0}$$

$${f}_{0 , 2} = {d}_{5 , 0} + {d}_{5 , 1} + {d}_{0 , 4}$$

$${f}_{1 , 2} = {d}_{4 , 0} + {d}_{4 , 1} + {d}_{0 , 3}$$

$${f}_{2 , 2} = {d}_{3 , 0} + {d}_{3 , 1}$$

$${f}_{0 , 3} = {d}_{2 , 0} + {d}_{2 , 1} + {d}_{0 , 2}$$

$${f}_{1 , 3} = {d}_{1 , 0} + {d}_{1 , 1}$$

$${f}_{2 , 3} = {d}_{0 , 0} + {d}_{0 , 1}$$

$${f}_{3 , 3} = {d}_{6 , 0}$$

$${f}_{4 , 3} = {d}_{5 , 0} + 4 {d}_{5 , 1} + 3 {d}_{0 , 4}$$

$${f}_{0 , 4} = {d}_{4 , 0} + 4 {d}_{4 , 1} + 3 {d}_{0 , 3}$$

$${f}_{1 , 4} = {d}_{3 , 0} + 4 {d}_{3 , 1}$$

$${f}_{2 , 4} = {d}_{2 , 0} + 4 {d}_{2 , 1} + 3 {d}_{0 , 2}$$

$${f}_{3 , 4} = {d}_{1 , 0} + 4 {d}_{1 , 1}$$

$${f}_{4 , 4} = {d}_{0 , 0} + 4 {d}_{0 , 1}$$

$$\tilde{f} = d {A}^{′} \\ = ( {d}_{0 , 0} {d}_{1 , 0} {d}_{2 , 0} {d}_{3 , 0} {d}_{4 , 0} {d}_{5 , 0} {d}_{6 , 0} {d}_{0 , 1} {d}_{1 , 1} {d}_{2 , 1} {d}_{3 , 1} {d}_{4 , 1} {d}_{5 , 1} {d}_{0 , 2} {d}_{0 , 3} {d}_{0 , 4} ) . \\ ( \begin{matrix}0 & 0 & 0 & 0 & 0 & 0 & 1 & 0 & 0 & 0 & 0 & 0 & 0 & 1 \\ 0 & 0 & 0 & 0 & 0 & 1 & 0 & 0 & 0 & 0 & 0 & 0 & 1 & 0 \\ 0 & 0 & 0 & 0 & 1 & 0 & 0 & 0 & 0 & 0 & 0 & 1 & 0 & 0 \\ 0 & 0 & 0 & 1 & 0 & 0 & 0 & 0 & 0 & 0 & 1 & 0 & 0 & 0 \\ 0 & 0 & 1 & 0 & 0 & 0 & 0 & 0 & 0 & 1 & 0 & 0 & 0 & 0 \\ 0 & 1 & 0 & 0 & 0 & 0 & 0 & 0 & 1 & 0 & 0 & 0 & 0 & 0 \\ 1 & 0 & 0 & 0 & 0 & 0 & 0 & 1 & 0 & 0 & 0 & 0 & 0 & 0 \\ 0 & 0 & 0 & 0 & 0 & 0 & 1 & 0 & 0 & 0 & 0 & 0 & 0 & 4 \\ 0 & 0 & 0 & 0 & 0 & 1 & 0 & 0 & 0 & 0 & 0 & 0 & 4 & 0 \\ 0 & 0 & 0 & 0 & 1 & 0 & 0 & 0 & 0 & 0 & 0 & 4 & 0 & 0 \\ 0 & 0 & 0 & 1 & 0 & 0 & 0 & 0 & 0 & 0 & 4 & 0 & 0 & 0 \\ 0 & 0 & 1 & 0 & 0 & 0 & 0 & 0 & 0 & 4 & 0 & 0 & 0 & 0 \\ 0 & 1 & 0 & 0 & 0 & 0 & 0 & 0 & 4 & 0 & 0 & 0 & 0 & 0 \\ 0 & 0 & 0 & 0 & 1 & 0 & 0 & 0 & 0 & 0 & 0 & 3 & 0 & 0 \\ 0 & 0 & 1 & 0 & 0 & 0 & 0 & 0 & 0 & 3 & 0 & 0 & 0 & 0 \\ 0 & 1 & 0 & 0 & 0 & 0 & 0 & 0 & 3 & 0 & 0 & 0 & 0 & 0\end{matrix} )$$

This code allows to recover any 2 node failures, however it is not MDS because there remains 1 extra parity symbol, f′_{0,1}, corresponding to the first column of A′.

In order to puncture this column we apply the procedure outlined in FIG. 15. In short, we need to shift the only nonzero element in that column horizontally to another column without breaking the properties of the code. This may only be possible with one single shift if the nonzero element is moved in one of the column positions freed up by the nonzero elements of the removed rows. The shifted element then is replaced by the value of the nonzero element that was previously removed. In this case the removed 5 rows of Ã read

$$( \begin{matrix}1 & 0 & 0 & 0 & 0 & 0 & 0 & 4 & 0 & 0 & 0 & 0 & 0 & 0 \\ 0 & 0 & 0 & 0 & 0 & 0 & 1 & 0 & 0 & 0 & 0 & 0 & 0 & 3 \\ 0 & 0 & 0 & 0 & 0 & 1 & 0 & 0 & 0 & 0 & 0 & 0 & 3 & 0 \\ 0 & 0 & 0 & 1 & 0 & 0 & 0 & 0 & 0 & 0 & 3 & 0 & 0 & 0 \\ 1 & 0 & 0 & 0 & 0 & 0 & 0 & 3 & 0 & 0 & 0 & 0 & 0 & 0\end{matrix} )$$

and the first viable column position, reading column wise from top left to bottom right, is column 4 with value 1. After applying this shift and removing the first column, we can test that the new reduced matrix is still a generator matrix of a code, which is now MDS and lowest density. The final parity symbols become

$${f}_{0 , 2} = {d}_{5 , 0} + {d}_{5 , 1} + {d}_{0 , 4}$$

$${f}_{1 , 2} = {d}_{4 , 0} + {d}_{4 , 1} + {d}_{0 , 3}$$

$${f}_{2 , 2} = {d}_{3 , 0} + {d}_{3 , 1} + {d}_{6 , 0}$$

$${f}_{0 , 3} = {d}_{2 , 0} + {d}_{2 , 1} + {d}_{0 , 2}$$

$${f}_{1 , 3} = {d}_{1 , 0} + {d}_{1 , 1}$$

$${f}_{2 , 3} = {d}_{0 , 0} + {d}_{0 , 1}$$

$${f}_{3 , 3} = {d}_{6 , 0}$$

$${f}_{4 , 3} = {d}_{5 , 0} + 4 {d}_{5 , 1} + 3 {d}_{0 , 4}$$

$${f}_{0 , 4} = {d}_{4 , 0} + 4 {d}_{4 , 1} + 3 {d}_{0 , 3}$$

$${f}_{1 , 4} = {d}_{3 , 0} + 4 {d}_{3 , 1}$$

$${f}_{2 , 4} = {d}_{2 , 0} + 4 {d}_{2 , 1} + 3 {d}_{0 , 2}$$

$${f}_{3 , 4} = {d}_{1 , 0} + 4 {d}_{1 , 1}$$

$${f}_{4 , 4} = {d}_{0 , 0} + 4 {d}_{0 , 1}$$

$$f = d A \\ = ( {d}_{0 , 0} {d}_{1 , 0} {d}_{2 , 0} {d}_{3 , 0} {d}_{4 , 0} {d}_{5 , 0} {d}_{6 , 0} {d}_{0 , 1} {d}_{1 , 1} {d}_{2 , 1} {d}_{3 , 1} {d}_{4 , 1} {d}_{5 , 1} {d}_{0 , 2} {d}_{0 , 3} {d}_{0 , 4} ) . \\ ( \begin{matrix}0 & 0 & 0 & 0 & 0 & 1 & 0 & 0 & 0 & 0 & 0 & 0 & 1 \\ 0 & 0 & 0 & 0 & 1 & 0 & 0 & 0 & 0 & 0 & 0 & 1 & 0 \\ 0 & 0 & 0 & 1 & 0 & 0 & 0 & 0 & 0 & 0 & 1 & 0 & 0 \\ 0 & 0 & 1 & 0 & 0 & 0 & 0 & 0 & 0 & 1 & 0 & 0 & 0 \\ 0 & 1 & 0 & 0 & 0 & 0 & 0 & 0 & 1 & 0 & 0 & 0 & 0 \\ 1 & 0 & 0 & 0 & 0 & 0 & 0 & 1 & 0 & 0 & 0 & 0 & 0 \\ 0 & 0 & 1 & 0 & 0 & 0 & 1 & 0 & 0 & 0 & 0 & 0 & 0 \\ 0 & 0 & 0 & 0 & 0 & 1 & 0 & 0 & 0 & 0 & 0 & 0 & 4 \\ 0 & 0 & 0 & 0 & 1 & 0 & 0 & 0 & 0 & 0 & 0 & 4 & 0 \\ 0 & 0 & 0 & 1 & 0 & 0 & 0 & 0 & 0 & 0 & 4 & 0 & 0 \\ 0 & 0 & 1 & 0 & 0 & 0 & 0 & 0 & 0 & 4 & 0 & 0 & 0 \\ 0 & 1 & 0 & 0 & 0 & 0 & 0 & 0 & 4 & 0 & 0 & 0 & 0 \\ 1 & 0 & 0 & 0 & 0 & 0 & 0 & 4 & 0 & 0 & 0 & 0 & 0 \\ 0 & 0 & 0 & 1 & 0 & 0 & 0 & 0 & 0 & 0 & 3 & 0 & 0 \\ 0 & 1 & 0 & 0 & 0 & 0 & 0 & 0 & 3 & 0 & 0 & 0 & 0 \\ 1 & 0 & 0 & 0 & 0 & 0 & 0 & 3 & 0 & 0 & 0 & 0 & 0\end{matrix} )$$

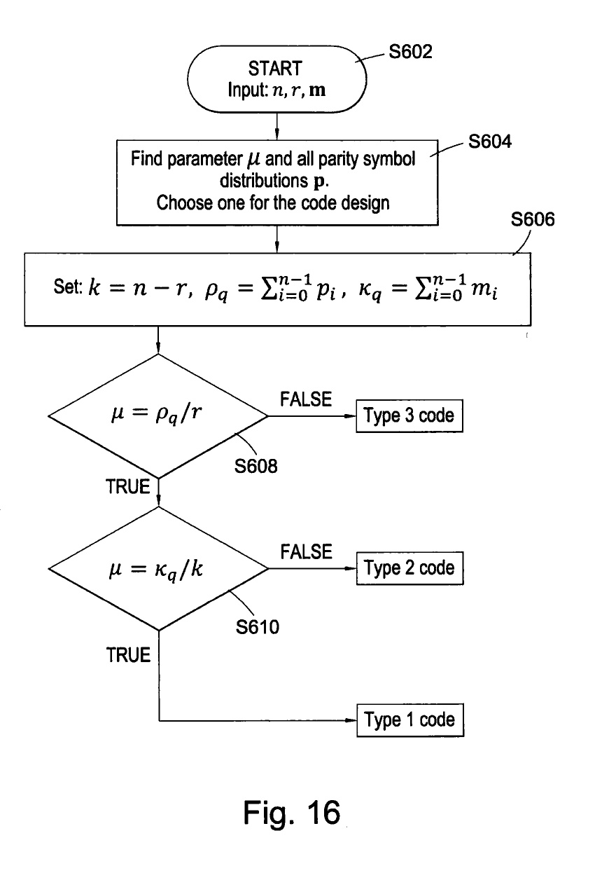

FIG. 16 shows a method of determining which type of code to be used. The method starts in step S602 in which an input of the number of nodes n, the number of erasures r, and the distribution of data symbols m is received. In step S604, the parameter p and all possible parity symbol distributions are determined. One of the parity symbol distributions is selected for the code design.

In step S606, the following quantities are calculated:

$$k = n - r$$

$${ρ}_{q} = {\sum }_{i = 0}^{n - 1} {p}_{i} {κ}_{q} = {\sum }_{i = 0}^{n - 1} {m}_{i}$$

In step S608, it is determined if μ=ρ_{q}/r, if this is not the case, then a type 3 code is required. If μ=ρ_{q}/r, then the method moves to step S610.

In step S610, it is determined if μ=κ_{q}/k. If this is the case, then a type 1 code is required. If μ≠κ_{q}/k, then a type 2 code is required.

There are several important properties an array code should have:
1. MDS property. For a given network size n with data distribution {mᵢ}ᵢ₌₀ⁿ⁻¹ capable of correcting any failure of up to r nodes, the number of parity symbols should be as small as possible.
2. Lowest density property. There are exactly r nonzero entries in each row
of A and up to k nonzero entries in each column of A, which yields a generator matrix with the lowest possible density of nonzero elements.
3. Finite alphabet. The nonzero entries of A belong to a finite field GF(q).
4. Generality of design. The construction is applicable to any number of nodes n and node failures r, furthermore it should work for all data rates {dᵢ}ᵢ₌₀ⁿ⁻¹.

The construction described herein encompasses all of the above properties.

Some additional properties of the array code described here are:

Node permutations. By applying a permutation to the nodes, i.e., relabeling of the nodes, which translates to a row and column permutation on matrix A, we can obtain a different code with the same optimal properties. In total, there are n! such permutations.

Duality. It can be shown that once an MDS code has been designed for n nodes, r=n−k maximum number of erasures, mᵢ information and pᵢ parity messages per node, the same construction can be used for the “dual” code if mᵢ+pᵢ=μ, ∀i; this is also a lowest density MDS array code. The dual code is characterised by the same number of nodes n but can correct k erasures when there are pᵢ data symbols and mᵢ parity symbols per node.

Extension to {mᵢ}ᵢ₌₀ⁿ⁻¹ not co-prime. If gcd{mᵢ}ᵢ₌₀ⁿ⁻¹=a, then the parity distribution has gcd {pᵢ}ᵢ₌₀ⁿ⁻¹=a. Therefore once a [n,k] irregular MDS array code has been designed for the data distribution {mᵢ/a}ᵢ₌₀ⁿ⁻¹, an extended MDS code can be easily constructed for the n-tuple {mᵢ}ᵢ₌₀ⁿ⁻¹. This extended family of codes is found by simply reusing the same mother code a times. In particular, the generator matrix of the extended code, Gₐ, is obtained by a Kronecker product

Gₐ=G [symbol] Iₐ (16)

where G is the generator matrix of the original code and Iₐ is the a×a identity matrix.

While the embodiments described above relate to monitoring of energy usage, those of skill in the art will appreciate that the coding schemes can be adapted for use in a variety of applications such as networks with high packet loss; video streaming over lossy channels; distributed network storage and redundant disk drives.

For example, one application is sending packets through a lossy channel. The data in the lost packets could be generated from the parity information of the received packets. In this example of the block erasure code could is used as a higher layer packet recovery mechanism whereby lost packets are recovered from the parity information of the received packets.

In this case the parameters would be determined based on some higher layer channel quality measurements, for example packet loss ratio or packet processing delay. An advantage of using the proposed block erasure code would be in the flexibility of the parameters choice.

The customisation of the coding parameters could be adapted depending on the network topology and other requirements, such as the level of protection needed and the maximum number of nodes involved in the coding operation. Before the code is generated there is a stage where the concentrator node (or a number of nodes in case of a distributed approach) acquires information on the network topology. This may be possible by using for example neighbour lists in routing protocols.

A decision is then made on the number of nodes involved in the failure protection scheme (parameter n), on the level of protection, i.e., how many block erasures the code should sustain (parameter r) and on the number of data symbols processed in parallel (parameters {mᵢ}ᵢ₌₀ⁿ⁻¹).

While certain embodiments have been described, these embodiments have been presented by way of example only, and are not intended to limit the scope of the inventions. Indeed, the novel methods, systems, devices and networks described herein may be embodied in a variety of other forms; furthermore, various omissions, substitutions and changes may be made without departing from the spirit of the inventions. The accompanying claims and their equivalents are intended to cover such forms or modifications as would fall within the scope and spirit of the inventions.

1. A method of generating an erasure code for a network comprising a plurality of nodes, wherein the nodes of the network store data symbols and the number of data symbols stored on a first node of the network is different from the number of data symbols stored on a second node of the network, the erasure code indicating the dependance of parity symbols stored by the nodes of the network on the data symbols such that the data symbols stored on nodes of the network can be determined from parity symbols and data symbols stored on other nodes of the network, the method comprising
determining from the distribution of data symbols among the nodes, an optimal parity symbol distribution;
based on the optimal parity symbol distribution and the distribution of data symbols, selecting a code generation method; and
generating the erasure code using the selected code generation method.

2. A method according to claim 1, wherein selecting a code generation method comprises selecting a code generation method from:
a first method comprising forming a first array indicating the dependance of the parity symbols on the data symbols, wherein the parity symbols and data symbols form a rectangular array;
a second method comprising adding at least one dummy data symbol to the data symbols and forming a second array indicating the dependance of the parity symbols on the data symbols; and
a third method comprising adding at least on dummy parity symbol to the data symbols and forming a third array indicating the dependance of the parity symbols on the data symbols.

3. A method according to claim 2 wherein the first method and/or the second method comprises generating a row wise erasure code from the first or second array.

4. A method according to claim 2, wherein the first method comprises arranging parity symbols by adding the parity symbols for each node to the column of the first array containing the data symbols corresponding to that node.

5. A method according to claim 2, wherein the second method comprises deriving a generator matrix from the second array and removing at least one row from the generator matrix, the at least one row corresponding to the at least one dummy data symbol.

6. A method according to claim 2, wherein the third method further comprises forming a generator matrix from the third array and puncturing a column from the generator matrix.

7. A method according to claim 1, wherein determining an optimal parity symbol distribution comprises calculating an optimal distribution of parity symbols such that the optimal distribution of parity symbols has the minimum number of parity symbols required to correct a set number of missing nodes.

8. A computer readable carrier medium carrying processor executable instructions which when executed on a processor cause the processor to carry out a method according to claim 1.

9. A data processing system comprising a processor configured to carry out the method of claim 1.

10. A concerntrator node of a wireless network comprising the data processing system of claim 9.

11. A decoder for decoding a received set of blocks, wherein a first block of the received set of blocks comprises a first number of data symbols and a second block of the received set of blocks comprises a second number, different from the first number, of data symbols, and wherein blocks of the received set of blocks comprise parity symbols, the decoder comprising
storage for a coding matrix which is derived from the Kronecker product of a totally nonsingular matrix with an antidiagonal matrix; and
a processor operable to determine data symbols of at least one erased block from the received set of blocks using the coding matrix.

12. A decoder according to claim 11 wherein the coding matrix is the Kronecker product of a totally nonsingular matrix with an antidiagonal matrix.

13. A decoder according to claim 11 wherein the coding matrix is a matrix derived by removing at least one row from the Kronecker product of a totally nonsingular matrix with an antidiagonal matrix.

14. A decoder according to claim 11 wherein the coding matrix is a matrix derived by removing at least one row and at least one column from the Kronecker product of a totally nonsingular matrix with an antidiagonal matrix.

15. An encoder for encoding a block of a plurality of blocks of an erasure code, wherein a first block of the erasure code comprises a first number of data symbols and a second block of the erasure code comprises a second number, different from the first number, of data symbols, the encoder being configured to set a plurality of parity symbols of the block using combinations of data symbols of other blocks of the plurality of blocks selected according to a column of a coding matrix which is derived from the Kronecker product of a totally non-singular matrix with an antidiagonal matrix.

16. An encoder according to claim 15 wherein the coding matrix is the Kronecker product of a totally nonsingular matrix with an antidiagonal matrix.

17. An encoder according to claim 15 wherein the coding matrix is a matrix derived by removing at least one row from the Kronecker product of a totally nonsingular matrix with an antidiagonal matrix.

18. An encoder according to claim 15 wherein the coding matrix is a matrix derived by removing at least one row and at least one column from the Kronecker product of a totally nonsingular matrix with an antidiagonal matrix.

19. A method of decoding a received set of blocks, wherein blocks of the received set of blocks comprise a plurality of data symbols and a plurality of parity symbols, and wherein a first block of the received set of blocks comprises a first number of data symbols and a second block of the received set of blocks comprises a second number, different from the first number, of data symbols, the received set of blocks being a subset of a complete set of blocks, the complete set of blocks comprising at least one erased block not included in the received set of blocks, the method comprising
determining the data symbols of the at least one erased block using a coding matrix which is derived from the Kronecker product of a totally nonsingular matrix with an antidiagonal matrix.

20. A method of encoding a block of a plurality of blocks of an erasure code, wherein a first block of the erasure code comprises a first number of data symbols and a second block of the erasure code comprises a second number, different from the first number, of data symbols, the method comprising
setting the parity symbols of the block using combinations of data symbols of other blocks of the plurality of blocks selected according to a column of an encoding matrix which is derived from the Kronecker product of a totally nonsingular matrix with an antidiagonal matrix.
